(19) United States
(12) Patent Application Publication
(10) Pub. No.: US 2013/0332790 A1
(43) Pub. Date: Dec. 12, 2013

(54) LDPC Decision Driven Equalizer Adaptation

(71) Applicants: Jin Lu, Lafayette, CO (US); Shaohua Yang, San Jose, CA (US)

(72) Inventors: Jin Lu, Lafayette, CO (US); Shaohua Yang, San Jose, CA (US)

(73) Assignee: LSI Corporation

(21) Appl. No.: 13/491,062

(22) Filed: Jun. 7, 2012

(51) Int. Cl. H03M 13/11; G06F 11/10; H03M 13/23

(52) U.S. Cl. 714/752; 714/786; 714/E11.032

(57) ABSTRACT

The present inventions are related to LDPC decision-driven equalizer adaptation. For example, a data processing apparatus is disclosed that includes an equalizer operable to yield equalized data, a low density parity check decoder operable to decode the equalized data to yield decoded data, and an equalizer adaptation circuit operable to adapt settings in the equalizer based in part on the decoded data.

### BACKGROUND

Various data processing systems have been developed including storage systems, cellular telephone systems, and radio transmission systems. In such systems data is transferred from a sender to a receiver via some medium. For example, in a storage system, data is sent from a sender (i.e., a write function) to a receiver (i.e., a read function) via a storage medium. As information is stored and transmitted in the form of digital data, errors are introduced that, if not corrected, can corrupt the data and render the information unusable. The effectiveness of any transfer is impacted by any losses in data caused by various factors. Many types of error checking systems have been developed to detect and correct errors in digital data. For example, Low Density Parity Check (LDPC) decoders may be used to iteratively perform parity checks while updating values in a block of data to correct errors.

Digital data may be equalized to reduce inter-symbol interference (ISI) based on a target response or partial response (PR) target before decoding in an LDPC decoder. For example, a digital finite impulse response (DFIR) filter may be used to equalize digital data based on a partial response target. A DFIR filter applies a mathematical operation to a digital data stream to achieve any of a wide range of desired frequency responses. As illustrated in FIG. 1, a DFIR filter 100 passes an input 102 through a series of delay elements 104, 106 and 110, multiplying the delayed signals by filter coefficients or tap weights 112, 114, 116 and 120, and summing the results to yield a filtered output 122. The outputs 130, 140 and 150 of each delay element 104, 106 and 110 and the input 102 form a tapped delay line and are referred to as taps. The number of delay elements 104, 106 and 110, and thus the number of taps 102, 130, 140 and 150 (also referred to as the order or length of the DFIR filter 100) may be increased to more finely tune the frequency response, but at the cost of increasing complexity. The DFIR filter 100 implements a filtering equation such as Y[n]=F₀X[n]+F₁X[n−1]+F₂X[n−2]+F₃X[n−3] for the three-delay filter illustrated in FIG. 1, or more generally Y[n]=F₀X[n]+F₁X[n−1]+F₂X[n−2]+ . . . +F₃X[n−L], where X[n] is the current input 102, the value subtracted from n represents the index or delay applied to each term, Fᵢ are the tap weights 112, 114, 116 and 120, Y[n] is the output 122 and L is the filter order. The input 102 is multiplied by tap weight 112 in a multiplier 124, yielding a first output term 126. The second tap 130 is multiplied by tap weight 114 in multiplier 132, yielding a second output term 134, which is combined with first output term 126 in an adder 136 to yield a first sum 148. The third tap 140 is multiplied by tap weight 116 in multiplier 142, yielding a third output term 144, which is combined with first sum 148 in adder 146 to yield a second sum 158. The fourth tap 150 is multiplied by tap weight 120 in multiplier 152, yielding a fourth output term 154, which is combined with second sum 158 in adder 156 to yield output 122. By changing the tap weights 25 112, 114, 116 and 120, the filtering applied to the input 102 by the DFIR filter 100 is adjusted to select the desired pass frequencies and stop frequencies.

LDPC decoders and equalizers may be used, for example, to process data sectors retrieved from a magnetic disk drive. Each data sector may have different noise, jitter and distortion characteristics or signal to noise ratios (SNR), which may be due, for example, to magnetic media defects, off-track writing, high fly height of magnetic write heads during a writing operation, large phase disturbance, etc. The throughput of a magnetic disk drive is affected by the number of read errors in a data sector, based in part on the SNR, and by the speed at which the read channel can recover from a read error by correcting the errors. The equalizer used to prepare data for an LDPC decoder may be pre-tuned based on the characteristics of a data sector as it is written. However, the equalizer settings may not be applicable to different data sectors or even to the original data sector given changing SNR and non-linear conditions.

### BRIEF SUMMARY

The present inventions are related to LDPC decision-driven equalizer adaptation. An equalizer such as, but not limited to, a DFIR is used to equalize digital data samples before they are processed in an LDPC decoder. The decisions or output from the LDPC decoder are used to adapt equalizer settings, tailoring the equalizer to the actual input data and SNR conditions. Decisions from the LDPC decoder are treated as ideal data for tuning the equalizer, in some embodiments using data that has converged in the LDPC decoder, in other embodiments using the LDPC decoder output after one or more global iterations, whether the data has converged or not. The equalizer is adapted based on the LDPC decoder output and a buffered copy of the input data corresponding to the LDPC decoder output. By adapting the equalizer to that particular sector or to a preceding sector, the equalizer better matches the actual channel conditions. The tuned equalizer can then be used to reprocess the sector or to process the next sector, better boosting the signal and suppressing the noise level to improve recovery of failed sectors.

This summary provides only a general outline of some embodiments according to the present invention. Many other objects, features, advantages and other embodiments of the present invention will become more fully apparent from the following detailed description, the appended claims and the accompanying drawings.

### BRIEF DESCRIPTION OF THE DRAWINGS

A further understanding of the various embodiments of the present invention may be realized by reference to the figures which are described in remaining portions of the specification.

FIG. 1 depicts a prior art DFIR filter;

FIG. 2 depicts a data processing circuit with an LDPC decoder, a first equalizer and a second tunable equalizer in accordance with one or more embodiments of the present inventions;

FIG. 3 depicts a data processing circuit with an LDPC decoder and a tunable equalizer in accordance with one or more embodiments of the present inventions;

FIG. 4 depicts a flow diagram of an operation for decoding data with equalizer adaptation based on converged LDPC decoder decisions in accordance with one or more embodiments of the present inventions;

FIG. 5 depicts a flow diagram of an operation for decoding data with equalizer adaptation based on LDPC decoder output after a number of global iterations in accordance with one or more embodiments of the present inventions;

FIG. 6 depicts a flow diagram of an operation for LDPC decision-driven equalizer adaptation in accordance with one or more embodiments of the present inventions;

FIG. 7 depicts a storage system with LDPC decision-driven equalizer adaptation in accordance with one or more embodiments of the present inventions; and

FIG. 8 depicts a wireless communication system with LDPC decision-driven equalizer adaptation in accordance with one or more embodiments of the present inventions.

### DETAILED DESCRIPTION OF THE INVENTION

The present inventions are related to LDPC decision-driven equalizer adaptation. An equalizer such as, but not limited to, a DFIR is used to equalize digital data samples before they are processed in an LDPC decoder. The LDPC decoder used in various embodiments may be any type of LDPC decoder, including binary and non-binary, layered and non-layered. LDPC technology is applicable to transmission of information over virtually any channel or storage of information on virtually any media. Transmission applications include, but are not limited to, optical fiber, radio frequency channels, wired or wireless local area networks, digital subscriber line technologies, wireless cellular, Ethernet over any medium such as copper or optical fiber, cable channels such as cable television, and Earth-satellite communications. Storage applications include, but are not limited to, hard disk drives, compact disks, digital video disks, magnetic tapes and memory devices such as DRAM, NAND flash, NOR flash, other non-volatile memories and solid state drives.

The decisions or output from the LDPC decoder are used to adapt equalizer settings, tailoring the equalizer to the actual input data and SNR conditions. Decisions from the LDPC decoder are treated as ideal data for tuning the equalizer, in some embodiments using data that has converged in the LDPC decoder, in other embodiments using the LDPC decoder output after one or more global iterations, whether the data has converged or not. The equalizer is adapted based on the LDPC decoder output and a buffered copy of the input data corresponding to the LDPC decoder output. In some embodiments in which the equalizer and LDPC decoder process data sectors from a hard disk drive, the LDPC decoder output and the buffered copy of the input data correspond to the same data sector. By adapting the equalizer to that particular sector or to a preceding sector, the equalizer better matches the actual channel conditions. The tuned equalizer can then be used to reprocess the sector or to process the next sector, better boosting the signal and suppressing the noise level to improve recovery of failed sectors.

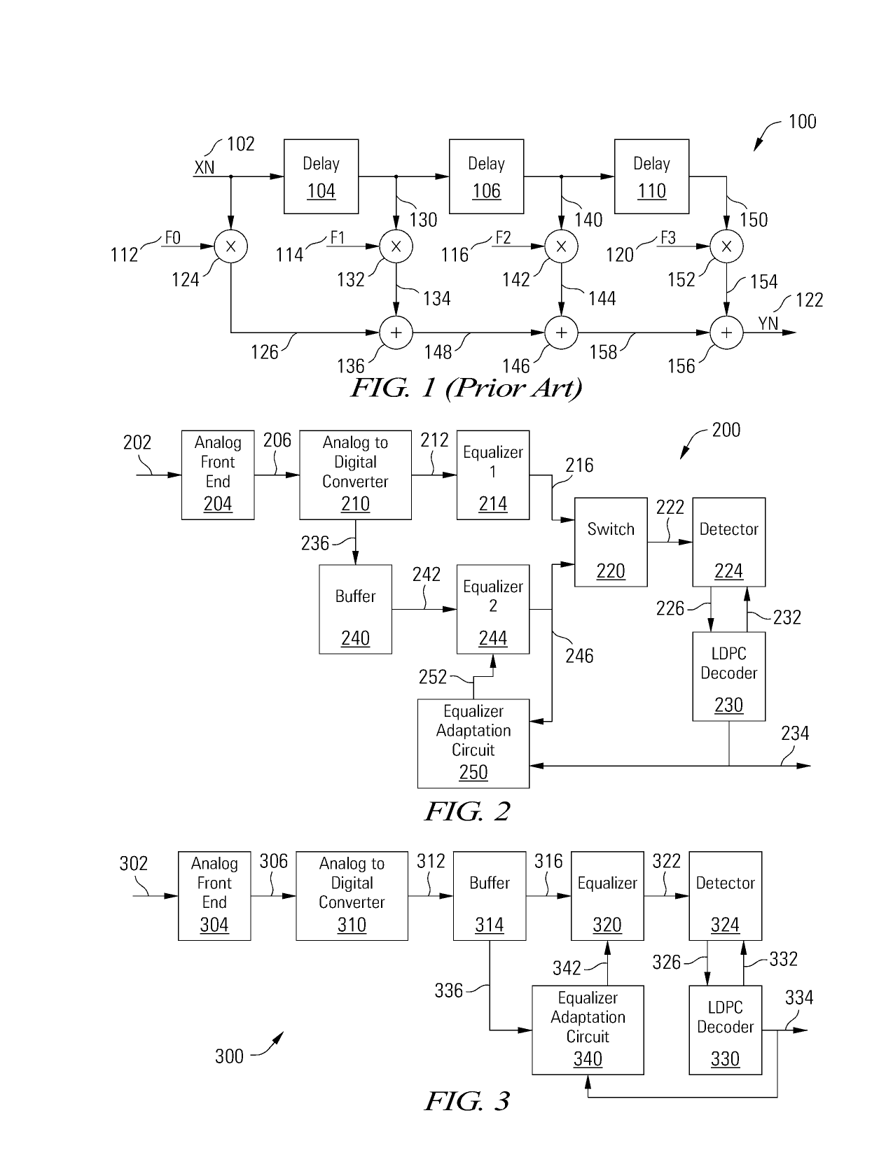

Turning to FIG. 2, a data processing circuit 200 is disclosed with a default equalizer 214 and a second tunable equalizer 244. In some embodiments, the data processing circuit 200 is a read channel used to decode LDPC encoded data retrieved from a hard disk drive. In some other embodiments, the data processing circuit 200 is used to decode LDPC encoded data received via a wireless transmission medium.

The data processing circuit 200 includes an analog front end 204 that receives and processes an analog signal 202 from the storage or transmission channel. Analog front end 204 may include, but is not limited to, an analog filter and an amplifier circuit as are known in the art. For example, the analog front end 204 may include a high pass filter, a variable gain amplifier (VGA), a compensation circuit for the magneto-resistive asymmetry (MRA) characteristic of a magnetic write head, etc. Based upon the disclosure provided herein, one of ordinary skill in the art will recognize a variety of circuitry that may be included as part of analog front end circuit 204. In some cases, the gain of a variable gain amplifier included as part of analog front circuit 204 may be modifiable, and the cutoff frequency and boost of an analog filter included in analog front end circuit 204 may be modifiable. Analog front end circuit 204 receives and processes the analog signal 202, and provides a processed analog signal 206 to an analog to digital converter circuit 210. In some cases, analog signal 202 is derived from a read/write head assembly in a storage or transmission channel that is disposed in relation to a storage medium. In other cases, analog signal 202 is derived from a receiver circuit in a storage or transmission channel that is operable to receive a signal from a transmission medium. The transmission medium may be wireless or wired such as, but not limited to, cable or optical connectivity. Based upon the disclosure provided herein, one of ordinary skill in the art will recognize a variety of sources from which analog input 202 may be derived.

Analog to digital converter circuit 210 converts processed analog signal 206 into a corresponding series of digital samples 212 or X samples. Analog to digital converter circuit 210 may be any circuit known in the art that is capable of producing digital samples corresponding to an analog input signal 206. Based upon the disclosure provided herein, one of ordinary skill in the art will recognize a variety of analog to digital converter circuits that may be used in relation to different embodiments of the present invention. In other embodiments, the digital samples 212 may be obtained directly from a digital storage device or digital transmission medium.

Digital samples 212 are provided to a default equalizer circuit 214. Equalizer circuit 214 applies an equalization algorithm to digital samples 212 to yield an equalized output 216 or Y samples. In some embodiments of the present invention, equalizer circuit 214 is a digital finite impulse response filter circuit as are known in the art. In these embodiments, the DFIR tap coefficients are pre-tuned according to expected channel conditions. The equalized output 216 includes LDPC-encoded digital data bits, equalized to reduce inter-symbol interference (ISI) in the equalizer 214 based on a target response or partial response (PR) target. The equalized output 216 may be stored in a Y memory (not shown) until a data detector circuit 224 is available and ready to begin processing equalized output 216.

The equalized output 216 is provided to a switch 220, operable to select as detector input 222 either the equalized output 216 from equalizer 214 or an equalized output 246 from tunable equalizer 244. The switch 220 may be used to enable the LDPC decision-driven equalizer adaptation disclosed herein by selecting equalized output 246 from tunable equalizer 244, or to disable the LDPC decision-driven equalizer adaptation by selecting the equalized output 216 from default equalizer 214. If the tunable equalizer 244 is repeatedly tuned during operation and read errors substantially increase during operation, for example if the tunable equalizer 244 to particularly noisy sector conditions which abruptly end, the equalized output 216 from default equalizer 214 may be selected in switch 220 for a sector, allowing the tunable equalizer 244 to be re-tuned to more normal sector conditions.

Data detector circuit 224 is operable to apply a data detection algorithm to a received codeword or data set. In some embodiments of the present inventions, data detector circuit 224 is a Viterbi algorithm data detector circuit as is known in the art. In other embodiments of the present invention, data detector circuit 224 is a maximum a posteriori data detector circuit as is known in the art. Of note, the general phrases “Viterbi data detection algorithm” or “Viterbi algorithm data detector circuit” are used in their broadest sense to mean any Viterbi detection algorithm or Viterbi algorithm detector circuit or variations thereof including, but not limited to, bi-direction Viterbi detection algorithm or bi-direction Viterbi algorithm detector circuit. Also, the general phrases “maximum a posteriori data detection algorithm” or “maximum a posteriori data detector circuit” are used in their broadest sense to mean any maximum a posteriori detection algorithm or detector circuit or variations thereof including, but not limited to, simplified maximum a posteriori data detection algorithm and a max-log maximum a posteriori data detection algorithm, or corresponding detector circuits. Based upon the disclosure provided herein, one of ordinary skill in the art will recognize a variety of data detector circuits that may be used in relation to different embodiments of the present invention.

Upon completion, data detector circuit 224 provides detector output 226. Detector output 226 includes soft data. As used herein, the phrase “soft data” is used in its broadest sense to mean reliability data with each instance of the reliability data indicating a likelihood that a corresponding bit position or group of bit positions has been correctly detected. In some embodiments of the present invention, the soft data or reliability data is log likelihood ratio data as is known in the art. Detected output 226 is provided to an LDPC decoder 230 for decoding. In some embodiments, detected output 226 may also be interleaved in a local interleaver circuit (not shown) to shuffle sub-portions (i.e., local chunks) of the data set included as detected output 226, and stored in a central memory circuit (not shown).

The LDPC decoder 230 used in various embodiments may be any type of LDPC decoder, including binary and non-binary, layered and non-layered. In some embodiments, the LDPC decoder 230 is a non-binary min-sum based LDPC decoder. Based upon the disclosure provided herein, one of ordinary skill in the art will recognize other decode algorithms that may be used in relation to different embodiments of the present invention. The LDPC decoder 230 applies a data decode algorithm to detected output 226 in a variable number of local iterations.

Where the LDPC decoder 230 fails to converge (i.e., fails to yield the originally written data set) and the number of local iterations through LDPC decoder 230 exceeds a threshold, the resulting decoded output may be provided as a decoded output 232 back to data detector circuit 224 for another global detection/decoding iteration through data detector circuit 224 and LDPC decoder 230. In some embodiments, decoded output 232 is stored in a central memory circuit (not shown) and passed through a local deinterleaver circuit (not shown) that rearranges decoded output 232 to reverse the shuffling originally performed by the local interleaver circuit. The decoded output 232 is used in the next global iteration to guide subsequent detection of a corresponding data set received as detector input 222.

Where the decoded output converges (i.e., yields the originally written data set) in the LDPC decoder 230, the resulting decoded output 234 is yielded, including hard decisions and soft LLR data giving the likelihood or confidence values about the hard decisions. The LDPC decoder 230 may use any suitable technique to determine whether data has converged, such as the number of violated parity checks during a local decoding iteration.

Digital samples 236 corresponding to digital samples 212 from analog to digital converter circuit 210 are also stored in a buffer 240 for use in tuning the tunable equalizer 244. Buffer 240 is used as to adjust the delay of stored digital samples 242 to align them with the decoded output 234 so that the stored digital samples 242 and decoded output 234 for a particular sector are available at the same time to adjust the tunable equalizer 244.

If the LDPC decoder 230 converged, in other words if the decoded output 234 is correct and matches the true data, the decoded output 234 is used as ideal data to tune the tunable equalizer 244. The stored digital samples 242 for the sector at decoded output 234 is equalized in tunable equalizer 244 using original pre-tuned settings to yield equalized output 246. The decoded output 234 and equalized output 246 are provided to an equalizer adaptation circuit 250 to generate new equalizer settings 252 for tunable equalizer 244. For example, equalizer adaptation circuit 250 may calculate new tap coefficients for tunable equalizer 244.

The equalizer adaptation circuit 250 convolves the decoded output 234 with the channel partial response target to yield an ideal equalized sample for the data sector. The equalizer adaptation circuit 250 is also operable to generate new equalizer settings 252 for tunable equalizer 244 that reduce the difference between the ideal equalized sample and the equalized output 246, using any suitable algorithm. For example, the equalizer adaptation circuit 250 may implement a least mean squares algorithm to find DFIR tap coefficients (e.g., 252) that produce the least mean squares of the error signal comprising the difference between the ideal equalized sample and the equalized output 246. However, the equalizer adaptation circuit 250 is not limited to any particular error reducing algorithm. The new equalizer settings 252 thus tune the tunable equalizer 244 to better adapt to the channel condition (noise, jitter, distortion, etc.). After updating the tunable equalizer 244 with the new equalizer settings 252, the tunable equalizer 244 may be used in place of equalizer 214 to generate new Y samples for the data detector circuit 224 by configuring the switch 220 to output the equalized output 246 from tunable equalizer 244 rather than the equalized output 216 from equalizer 214. The switch 220 may also be switched during operation to turn equalizer adaptation on or off.

In some embodiments, the data processing circuit 200 uses the default equalizer 214 when processing the first sector, and uses the decoded output 234 if it converges in the LDPC decoder 230 to tune the tunable equalizer 244 based on the first sector results. The newly tuned tunable equalizer 244 is then used to when processing the second sector, and if the decoded output 234 converges in the LDPC decoder 230 for the second sector, it is used to again tune the tunable equalizer 244 based on the second sector results, and so on. This technique is based on the assumption that the conditions for one sector will be similar to a neighboring sector, an assumption that is typically true. This allows an equalizer tuning performed for one sector to be used to improve the equalization and decoding of the next sector, and so on. Thus, the actual channel conditions are better matched in the data processing circuit 200 in a rapidly adapting manner, yielding better detection and decoding performance simply and efficiently.

In some embodiments, the tunable equalizer 244 is tuned after each sector which converges in LDPC decoder 230 to yield a decoded output 234 that can be used to generate an ideal equalized sample. In other embodiments, the tunable equalizer 244 is tuned after one or more global detection/decoding iterations in the data detector circuit 224 and LDPC decoder 230, whether the data has converged or not. In the latter embodiments, the tunable equalizer 244 is tuned for a particular sector, and new Y samples for that sector can be processed during later global iterations. Thus, equalizer tuning can be performed during processing of a single sector. In some instances, the tunable equalizer 244 may be tuned using only the hard decisions in decoded output 234 with high likelihood or confidence values or with likelihood values greater than a threshold value.

In the embodiment of FIG. 2, the digital samples 236 are buffered in buffer 240 and equalized in tunable equalizer 244 to produce equalized output 246, which is used by equalizer adaptation circuit 250 to tune the tunable equalizer 244. In other embodiments, the tunable equalizer 244 may receive digital samples 236 from analog to digital converter circuit 210, with the equalized output 246 buffered before being used by equalizer adaptation circuit 250 to tune the tunable equalizer 244. Thus, the alignment between samples from analog to digital converter circuit 210 and the decoded output 234 may be performed either before or after tunable equalizer 244.

Turning to FIG. 3, a data processing circuit 300 with an LDPC decoder 330 and a tunable equalizer 320 is depicted in accordance with one or more embodiments of the present inventions. In this embodiment, a single equalizer 320 is included, which can be tuned to channel conditions during operation or which can be returned to a default tuning by equalizer adaptation circuit 340.

The data processing circuit 300 includes an analog front end 304 that receives and processes an analog signal 302 from the storage or transmission channel. Analog front end 304 may include, but is not limited to, an analog filter and an amplifier circuit as are known in the art. Based upon the disclosure provided herein, one of ordinary skill in the art will recognize a variety of circuitry that may be included as part of analog front end circuit 304. Analog front end circuit 304 receives and processes the analog signal 302, and provides a processed analog signal 306 to an analog to digital converter circuit 310. In some cases, analog signal 302 is derived from a read/write head assembly in a storage or transmission channel that is disposed in relation to a storage medium. In other cases, analog signal 302 is derived from a receiver circuit in a storage or transmission channel that is operable to receive a signal from a transmission medium. The transmission medium may be wireless or wired such as, but not limited to, cable or optical connectivity. Based upon the disclosure provided herein, one of ordinary skill in the art will recognize a variety of sources from which analog input 302 may be derived.

Analog to digital converter circuit 310 converts processed analog signal 306 into a corresponding series of digital samples 312 or X samples. Analog to digital converter circuit 310 may be any circuit known in the art that is capable of producing digital samples corresponding to an analog input signal 306. Based upon the disclosure provided herein, one of ordinary skill in the art will recognize a variety of analog to digital converter circuits that may be used in relation to different embodiments of the present invention. In other embodiments, the digital samples 312 may be obtained directly from a digital storage device or digital transmission medium.

Digital samples 312 are stored in a buffer 314 for use in tuning the tunable equalizer 320. Buffer 314 is used as to adjust the delay of stored digital samples 316 to align them with the decoded output 334 of the LDPC decoder 330 when tuning equalizer 320. The stored digital samples 316 pass through buffer 314 to equalizer 320, as well as being stored for later use in tuning equalizer 320.

Stored digital samples 316 are provided to a tunable equalizer 320. Equalizer 320 applies an equalization algorithm to stored digital samples 316 to yield an equalized output 322 or Y samples. In some embodiments of the present invention, equalizer 320 is a digital finite impulse response filter circuit as are known in the art. In these embodiments, the DFIR tap coefficients are pre-tuned according to expected channel conditions. The equalized output 322 includes LDPC-encoded digital data bits, equalized to reduce inter-symbol interference (ISI) in the equalizer 320 based on a target response or partial response (PR) target. The equalized output 322 may be stored in a Y memory (not shown) until a data detector circuit 324 is available and ready to begin processing equalized output 322.

Data detector circuit 324 is operable to apply a data detection algorithm to a received codeword or data set. In some embodiments of the present inventions, data detector circuit 324 is a Viterbi algorithm data detector circuit as is known in the art. In other embodiments of the present invention, data detector circuit 324 is a maximum a posteriori data detector circuit as is known in the art. Based upon the disclosure provided herein, one of ordinary skill in the art will recognize a variety of data detector circuits that may be used in relation to different embodiments of the present invention.

Upon completion, data detector circuit 324 provides detector output 326. Detector output 326 includes soft data. Detected output 326 is provided to the LDPC decoder 330 for decoding. In some embodiments, detected output 326 may also be interleaved in a local interleaver circuit (not shown) to shuffle sub-portions (i.e., local chunks) of the data set included as detected output 326, and stored in a central memory circuit (not shown).

The LDPC decoder 330 used in various embodiments may be any type of LDPC decoder, including binary and non-binary, layered and non-layered. In some embodiments, the LDPC decoder 330 is a non-binary min-sum based LDPC decoder. Based upon the disclosure provided herein, one of ordinary skill in the art will recognize other decode algorithms that may be used in relation to different embodiments of the present invention. The LDPC decoder 330 applies a data decode algorithm to detected output 326 in a variable number of local iterations.

Where the LDPC decoder 330 fails to converge and the number of local iterations through LDPC decoder 330 exceeds a threshold, the resulting decoded output may be provided as a decoded output 332 back to data detector circuit 324 for another global detection/decoding iteration through data detector circuit 324 and LDPC decoder 330. In some embodiments, decoded output 332 is stored in a central memory circuit (not shown) and passed through a local deinterleaver circuit (not shown) that rearranges decoded output 332 to reverse the shuffling originally performed by the local interleaver circuit. The decoded output 332 is used in the next global iteration to guide subsequent detection of a corresponding data set received as detector input 322.

Where the decoded output converges in the LDPC decoder 330, the resulting decoded output 334 is yielded, including hard decisions and soft LLR data giving the likelihood or confidence values about the hard decisions. The LDPC decoder 330 may use any suitable technique to determine whether data has converged, such as the number of violated parity checks during a local decoding iteration.

If the LDPC decoder 330 converged, the decoded output 334 is used as ideal data to tune the equalizer 320. The stored digital samples 316 corresponding to the sector at decoded output 334 is equalized in equalizer 314 to yield equalized output 322, so that the equalized output 322 and the decoded output 334 for the same sector are both available to equalizer adaptation circuit 340. In other embodiments, the equalized output 322 may be buffered rather than digital samples 312. The decoded output 334 and equalized output 322 are provided to equalizer adaptation circuit 340 to generate new equalizer settings 342 for tunable equalizer 320. For example, equalizer adaptation circuit 340 may calculate new tap coefficients for tunable equalizer 320.

The equalizer adaptation circuit 340 convolves the decoded output 334 with the channel partial response target to yield an ideal equalized sample for the data sector. The equalizer adaptation circuit 340 is also operable to generate new equalizer settings 342 for tunable equalizer 320 that reduce the difference between the ideal equalized sample and the equalized output 322, using any suitable algorithm. For example, the equalizer adaptation circuit 340 may implement a least mean squares algorithm to find DFIR tap coefficients (e.g., 342) that produce the least mean squares of the error signal comprising the difference between the ideal equalized sample and the equalized output 322. However, the equalizer adaptation circuit 340 is not limited to any particular error reducing algorithm. The new equalizer settings 342 thus tune the tunable equalizer 320 to better adapt to the channel condition (noise, jitter, distortion, etc.).

In some embodiments, the equalizer 320 is tuned after each sector which converges in LDPC decoder 330 to yield a decoded output 334 that can be used to generate an ideal equalized sample. In other embodiments, the equalizer 320 is tuned after one or more global detection/decoding iterations in the data detector circuit 324 and LDPC decoder 330, whether the data has converged or not. In the latter embodiments, the equalizer 320 is tuned for a particular sector, and new Y samples for that sector can be processed during later global iterations. Thus, equalizer tuning can be performed during processing of a single sector. In some instances, the equalizer 320 may be tuned using only the hard decisions in decoded output 334 with high likelihood or confidence values or with likelihood values greater than a threshold value.

In some embodiments, the equalizer 320 is tuned after each sector which converges in LDPC decoder 330 to yield a decoded output 334 that can be used to generate an ideal equalized sample. In other embodiments, the equalizer 320 is tuned after one or more global detection/decoding iterations in the data detector circuit 324 and LDPC decoder 330, whether the data has converged or not. In the latter embodiments, the equalizer 320 is tuned for a particular sector, and new Y samples for that sector can be processed during later global iterations. Thus, equalizer tuning can be performed during processing of a single sector. In some instances, the equalizer 320 may be tuned using only the hard decisions in decoded output 334 with high likelihood or confidence values or with likelihood values greater than a threshold value.

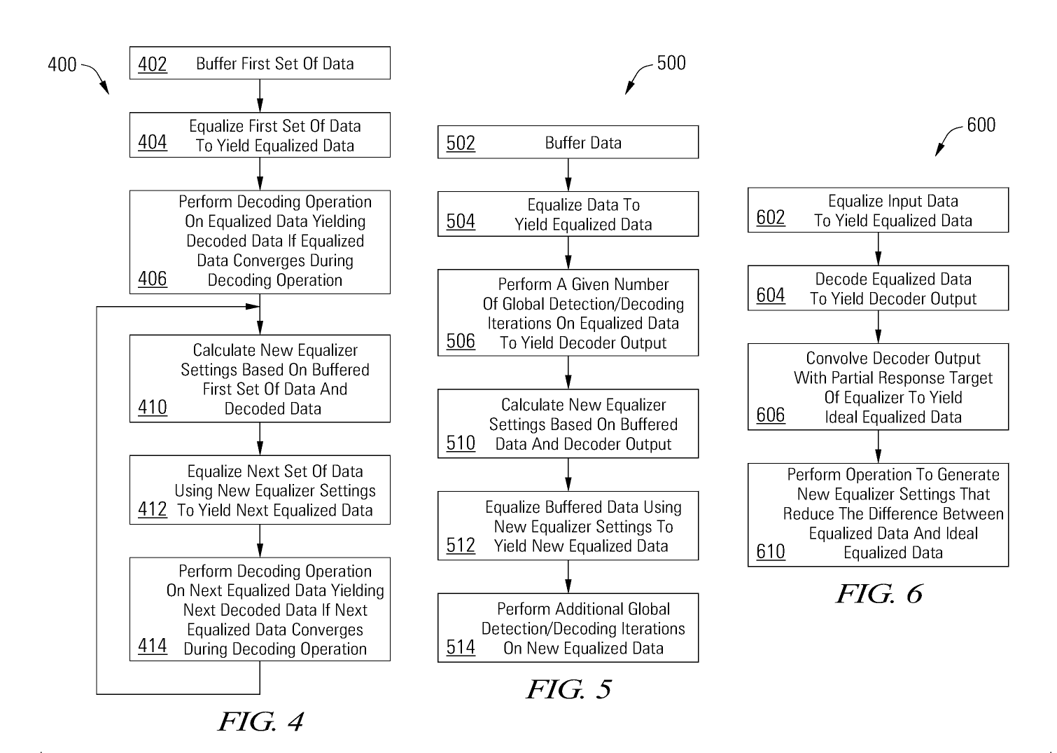

Turning to FIG. 4, a flow diagram 400 depicts an operation for decoding data with equalizer adaptation based on converged LDPC decoder decisions in accordance with one or more embodiments of the present inventions. Following flow diagram 400, a first set of data is buffered. (Block 402) The first set of data may correspond, for example, to digital data samples for a first data sector. The first set of data is equalized to yield equalized data. (Block 404) For example, the first set of data may be passed through a DFIR filter with tap coefficients pre-tuned to apply a partial response target based on expected channel conditions. A decoding operation is performed on the equalized data, yielding decoded data as ideal data if the equalized data converges during the decoding operation. (Block 406) New equalizer settings are calculated based on the buffered first set of data and the decoded data. (Block 410) The next set of data is equalized using the new equalizer settings to yield next equalized data. (Block 412) The next set of data may correspond, for example, to digital data samples for a second data sector, which are equalized with tuned new equalizer settings based on the ideal data that converged from the first data sector. A decoding operation is performed on the next equalized data, yielding next decoded data as ideal data if the next equalized data converged during the decoding operation. (Block 414) The new ideal data resulting from the next set of data may then be used to tune the equalizer at block 410, with the equalizing/decoding/tuning process continuing as new sectors are read and processed.

Turning to FIG. 5, a flow diagram 500 depicts an operation for decoding data with equalizer adaptation based on LDPC decoder output after a number of global iterations in accordance with one or more embodiments of the present inventions. Following flow diagram 500, data is buffered. (Block 502) The data may correspond, for example to digital data sectors for a data sector. The data is equalized to yield equalized data. (Block 504) For example, the data may be passed through a DFIR filter with tap coefficients pre-tuned to apply a partial response target based on expected channel conditions. A given number of global detection/decoding iterations are performed on the equalized data to yield a decoder output. (Block 506) New equalizer settings are calculated based on the buffered data and the decoder output. (Block 510) In some embodiments, for example, new equalizer settings are calculated after the first global iteration, whether the data converges or not. Typically, the decoder output is significantly better or closer to the correct data than the equalized data even after a single global iteration. In some embodiments, only data in the decoder output having high confidence or likelihood values are used to calculate new equalizer settings. The buffered data is then equalized using the new equalizer settings to yield new equalized data. (Block 512) Additional global detection/decoding iterations are performed on the new equalized data. (Block 514) This allows equalization to be tuned to actual channel conditions for a sector while that sector is still being decoded, increasing SNR and reducing the risk of read errors.

Turning to FIG. 6, a flow diagram 600 depicts an operation for LDPC decision-driven equalizer adaptation in accordance with one or more embodiments of the present inventions. The operation depicted in flow diagram 600 may be used, for example, in the decoding operations of FIGS. 4 and 5 to tune the equalizer, and in equalizer adaptation circuits 250 and 340 of FIGS. 2 and 3. Following flow diagram 600, input data is equalized to yield equalized data. (Block 602) This may be done, for example, using pre-tuned settings in an equalizer or using a custom tuning performed previously, such as using decoded data from the preceding data sector. The equalized data is decoded to yield a decoder output. (Block 604) The decoder output is convolved with a partial response target to yield ideal equalized data. (Block 606) New equalizer settings are generated using an operation to reduce the difference between the equalized data and ideal equalized data. (Block 610) For example, a least mean squares algorithm may be used to reduce the difference between the equalized data and ideal equalized data, yielding DFIR tap coefficients for an equalizer.

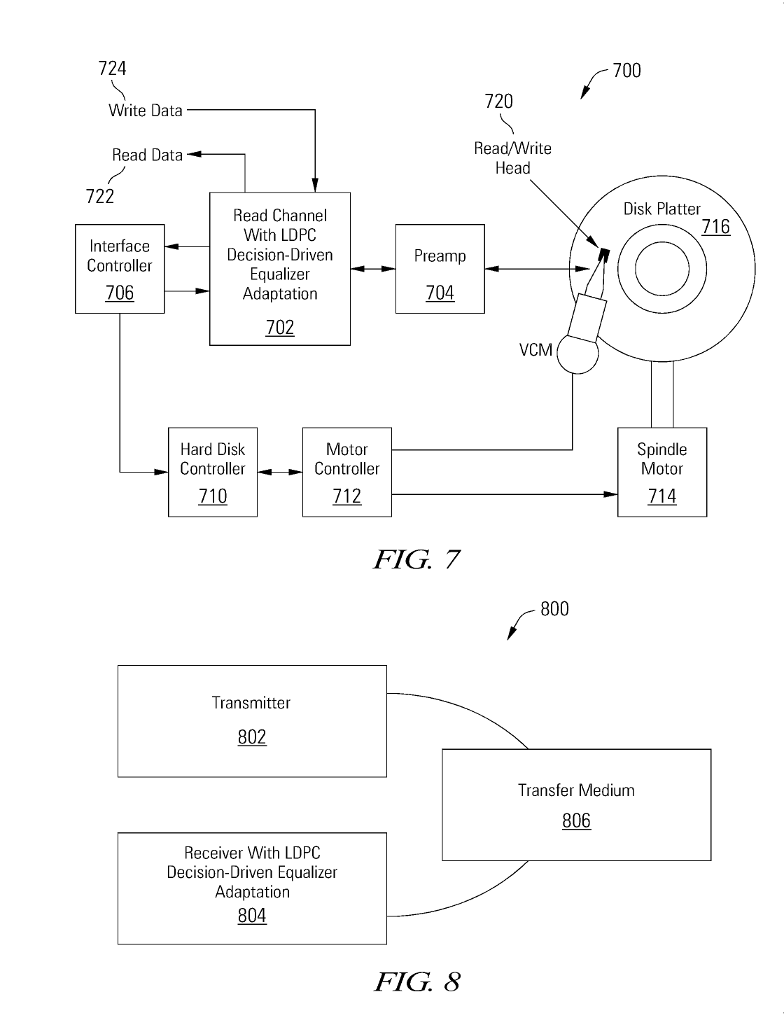

Although the LDPC decision-driven equalizer adaptation disclosed herein is not limited to any particular application, several examples of applications are presented in FIGS. 7 and 8 that benefit from embodiments of the present inventions. Turning to FIG. 7, a storage system 700 is illustrated as an example application of LDPC decision-driven equalizer adaptation. The storage system 700 includes a read channel circuit 702 with LDPC decision-driven equalizer adaptation. Storage system 700 may be, for example, a hard disk drive. Storage system 700 also includes a preamplifier 704, an interface controller 706, a hard disk controller 710, a motor controller 712, a spindle motor 714, a disk platter 716, and a read/write head assembly 720. Interface controller 706 controls addressing and timing of data to/from disk platter 716. The data on disk platter 716 consists of groups of magnetic signals that may be detected by read/write head assembly 720 when the assembly is properly positioned over disk platter 716. In one embodiment, disk platter 716 includes magnetic signals recorded in accordance with either a longitudinal or a perpendicular recording scheme.

In a typical read operation, read/write head assembly 720 is accurately positioned by motor controller 712 over a desired data track on disk platter 716. Motor controller 712 both positions read/write head assembly 720 in relation to disk platter 716 and drives spindle motor 714 by moving read/write head assembly 720 to the proper data track on disk platter 716 under the direction of hard disk controller 710. Spindle motor 714 spins disk platter 716 at a determined spin rate (RPMs). Once read/write head assembly 720 is positioned adjacent the proper data track, magnetic signals representing data on disk platter 716 are sensed by read/write head assembly 720 as disk platter 716 is rotated by spindle motor 714. The sensed magnetic signals are provided as a continuous, minute analog signal representative of the magnetic data on disk platter 716. This minute analog signal is transferred from read/write head assembly 720 to read channel circuit 702 via preamplifier 704. Preamplifier 704 is operable to amplify the minute analog signals accessed from disk platter 716. In turn, read channel circuit 702 decodes and digitizes the received analog signal to recreate the information originally written to disk platter 716. This data is provided as read data 722 to a receiving circuit. As part of decoding the received information, read channel circuit 702 processes the received signal using an equalizer and LDPC decoder, tuning or adapting the equalizer based on LDPC decoder decisions as disclosed herein. A write operation is substantially the opposite of the preceding read operation with write data 724 being provided to read channel circuit 702. This data is then encoded and written to disk platter 716.

It should be noted that storage system 700 may be integrated into a larger storage system such as, for example, a RAID (redundant array of inexpensive disks or redundant array of independent disks) based storage system. Such a RAID storage system increases stability and reliability through redundancy, combining multiple disks as a logical unit. Data may be spread across a number of disks included in the RAID storage system according to a variety of algorithms and accessed by an operating system as if it were a single disk. For example, data may be mirrored to multiple disks in the RAID storage system, or may be sliced and distributed across multiple disks in a number of techniques. If a small number of disks in the RAID storage system fail or become unavailable, error correction techniques may be used to recreate the missing data based on the remaining portions of the data from the other disks in the RAID storage system. The disks in the RAID storage system may be, but are not limited to, individual storage systems such storage system 700, and may be located in close proximity to each other or distributed more widely for increased security. In a write operation, write data is provided to a controller, which stores the write data across the disks, for example by mirroring or by striping the write data. In a read operation, the controller retrieves the data from the disks. The controller then yields the resulting read data as if the RAID storage system were a single disk.

Turning to FIG. 8, a wireless communication system 800 or data transmission device including a receiver 804 with LDPC decision-driven equalizer adaptation is shown in accordance with some embodiments of the present inventions. Communication system 800 includes a transmitter 802 that is operable to transmit encoded information via a transfer medium 806 as is known in the art. The encoded data is received from transfer medium 806 by receiver 804. As part of the processing of the encoded data, receiver 804 processes the received signal using an equalizer and LDPC decoder, tuning or adapting the equalizer based on LDPC decoder decisions as disclosed herein.

It should be noted that the various blocks discussed in the above application may be implemented in integrated circuits along with other functionality. Such integrated circuits may include all of the functions of a given block, system or circuit, or a portion of the functions of the block, system or circuit. Further, elements of the blocks, systems or circuits may be implemented across multiple integrated circuits. Such integrated circuits may be any type of integrated circuit known in the art including, but are not limited to, a monolithic integrated circuit, a flip chip integrated circuit, a multichip module integrated circuit, and/or a mixed signal integrated circuit. It should also be noted that various functions of the blocks, systems or circuits discussed herein may be implemented in either software or firmware. In some such cases, the entire system, block or circuit may be implemented using its software or firmware equivalent. In other cases, the one part of a given system, block or circuit may be implemented in software or firmware, while other parts are implemented in hardware.

In conclusion, the present invention provides novel systems, devices, methods and arrangements for LDPC decision-driven equalizer adaptation. While detailed descriptions of one or more embodiments of the invention have been given above, various alternatives, modifications, and equivalents will be apparent to those skilled in the art without varying from the spirit of the invention. Therefore, the above description should not be taken as limiting the scope of the invention, which is defined by the appended claims.

What is claimed is:

1. A data processing apparatus comprising:
an equalizer operable to yield equalized data;
a low density parity check decoder operable to decode the equalized data to yield decoded data; and
an equalizer adaptation circuit operable to adapt settings in the equalizer based in part on the decoded data.

2. The data processing apparatus of claim 1, wherein the equalizer adaptation circuit is operable to convolve the decoded data with a partial response target to yield ideal equalized data.

3. The data processing apparatus of claim 2, wherein the equalizer adaptation circuit is further operable to minimize a difference between the equalized data and the ideal equalized data to yield the settings.

4. The data processing apparatus of claim 3, wherein the equalized data and the ideal equalized data correspond to a same input data set.

5. The data processing apparatus of claim 3, wherein the equalizer adaptation circuit is operable to minimize the difference between the equalized data and the ideal equalized data using a least mean squares operation to yield the settings.

6. The data processing apparatus of claim 1, further comprising a detector operable to perform a data detection process on the equalized data and to iteratively process the equalized data with the low density parity check decoder.

7. The data processing apparatus of claim 6, wherein the equalizer adaptation circuit adapts the settings in the equalizer based in part on the decoded data at an output of the low density parity check decoder after a number or global iterations in the detector and the low density parity check decoder.

8. The data processing apparatus of claim 7, wherein the equalizer adaptation circuit adapts the settings in the equalizer based in part on the decoded data at an output of the low density parity check decoder even if the decoded data has not fully converged.

9. The data processing apparatus of claim 7, wherein the equalizer adaptation circuit adapts the settings in the equalizer based in part on portions of the decoded data having likelihood values greater than a threshold.

10. The data processing apparatus of claim 1, wherein the equalizer adaptation circuit is operable to adapt the settings in the equalizer based in part on the decoded data after the decoded data has converged in the low density parity check decoder.

11. The data processing apparatus of claim 10, wherein the equalizer adaptation circuit adapts the settings based upon a first set of input data, and wherein the adapted settings in the equalizer are used to yield next equalized data for a second set of input data.

12. The data processing apparatus of claim 1, further comprising a buffer operable to store input data samples, wherein the equalizer is operable to equalize the data samples from the buffer to yield the equalized data, and wherein the buffer is operable to align the equalized data with the decoded data for the equalizer adaptation circuit.

13. The data processing apparatus of claim 1, further comprising a default equalizer and a switch, wherein the switch is operable to select between an equalizer output and a default equalizer output to yield the equalized data for the low density parity check decoder.

14. The data processing apparatus of claim 1, wherein at least the equalizer, the low density parity check decoder and the equalizer adaptation circuit are implemented as an integrated circuit.

15. The data processing apparatus of claim 1, wherein the data processing apparatus is incorporated in a storage device.

16. The data processing apparatus of claim 15, wherein the storage device comprises a redundant array of independent disks.

17. The data processing apparatus of claim 1, wherein at least the equalizer, the low density parity check decoder and the equalizer adaptation circuit are incorporated in a transmission system.

18. A method for adapting equalizer settings in a data processing system, comprising:
equalizing input data to yield equalized data;
decoding the equalized data to yield a decoder output;
convolving the decoder output with a partial response target to yield ideal equalized data; and
generating new equalizer settings using an algorithm to reduce a difference between the ideal equalized data and the equalized data.

19. The method of claim 18, wherein generating the new equalizer settings comprises generating digital finite impulse response filter tap coefficients using a least mean squares algorithm on the ideal equalized data and the equalized data.

20. A storage system comprising:
a storage medium maintaining a data set;
a read/write head assembly operable to sense the data set on the storage medium;
a data processing circuit operable to correct errors in the data set, comprising:
an equalizer operable to yield equalized data for the data set;
a low density parity check decoder operable to decode the equalized data to yield decoded data; and
an equalizer adaptation circuit operable to adapt settings in the equalizer based in part on the decoded data.
